(19) United States
(12) Patent Application Publication
(10) Pub. No.: US 2004/0246033 A1
(43) Pub. Date: Dec. 9, 2004

(54) Synchronizer signal generator device and process for generating a synchronizer signal

(75) Inventors: Georg Eggers, Munchen (DE); Ralf Schneider, Munchen (DE)

Correspondence Address: MORRISON & FOERSTER LLP, 1650 TYSONS BOULEVARD, SUITE 300, MCLEAN, VA, 22102, US

(73) Assignee: Infineon Technologies AG, Munchen (DE)

(21) Appl. No.: 10/801,130

(22) Filed: Mar. 16, 2004

(30) Foreign Application Priority Data
Mar. 17, 2003 (DE) 103 12 497.7

(51) Int. Cl. H03L 7/00

(52) U.S. Cl. 327/141

(57) ABSTRACT

The invention relates to a process for generating a synchronizer pulse, in particular a clock pulse, as well as a synchronizer signal generator device, which is connected to an electronic system, and which emits a synchronizer signal of a particular frequency, which is transferred to at least one device of the electronic system, whereby at least one device is provided with its impedance selected so that a resonance oscillatory circuit—of which the resonance essentially coincides with the frequency of the synchronizer signal—is created for the synchronizer signal generator device.

### CLAIM FOR PRIORITY

This application claims the benefit of priority to German Application No. 103 12 497.7, filed in the German language on Mar. 17, 2003, the contents of which are hereby incorporated by reference.

### TECHNICAL FIELD OF THE INVENTION

The invention relates to a synchronizer signal generator device and process for generating a synchronizer signal, in particular a clock signal, e.g. for semi-conductor components.

### BACKGROUND OF THE INVENTION

With semi-conductor components, e.g. those with corresponding integrated (analog and/or digital) computer circuits, semi-conductor memory components such as functional memory components (PLAs, PALs, etc.) and table memory components (e.g. ROMs or RAMs, in particular SRAMs and DRAMs (DRAM=Dynamic Random Access Memory and/or Dynamic Read/Write Memory)) so-called clock signals are used for the chronological co-ordination of the processing, relaying and transfer of data.

The clock signals may for instance be generated by an external clock signal generator device, and relayed via one or more corresponding clock signal lines to one or more semi-conductor components (in particular to special clock signal pins provided there).

For generating the clock signal, the clock generator device may have a driver device, e.g. consisting of a pull-up and a pull-down switching device. The pull-up switching device may for instance be connected to the supply voltage and the pull-down switching device to ground.

The pull-up and pull-down switching devices are connected in series and may have one or several transistors (always connected in parallel), whereby the transistor(s) provided in the pull-up switching device may be inverted in relation to the transistor(s) in the pull-down switching device. For example, the pull-up switching device may have one or more p-channel MOSFETS (connected in parallel), and the pull-down switching device one or more n-channel MOSFETs (connected in parallel).

The clock signal pulses generated by the above conventional clock signal generator device—in particular by its driver with a pull-up and a pull-down switching device—are essentially rectangular, i.e. for instance alternately in a state of “high logic”, and “low logic”. For emitting a “high logic” clock signal the pull-up switching device may be switched on, i.e. brought into a conductive state, and the pull-down switching device switched off, i.e. brought into a non-conductive state; a “high logic” clock signal is then emitted at the clock signal line between the pull-up and the pull-down switching devices.

Conversely, for emitting a “low logic” clock signal the pull-up switching device may be switched off, i.e. brought into a non-conductive state, and the pull-down switching device switched on, i.e. brought into a conductive state; the clock signal emitted at the clock-pulse line is then “low logic”.

The driver device (and/or its pull-up and pull-down switching device) is controlled in such a way by an appropriate control device (e.g. one with a quartz oscillator) that “low logic” and “high logic” clock signal pulses are emitted at the clock signal line in strictly regular chronological succession.

In the above semi-conductor components receiving the clock signal, the data can then be relayed, processed or transferred by each ascending clock signal flank of the clock signal (or alternatively e.g. by each descending clock signal flank), whereby the chronological co-ordination and/or synchronization of data relays (and/or data processing or transfers) can be achieved.

The clock signal line (and/or the semi-conductor component(s) connected to it) represents a capacitive load for the driver device. This means that a charging current flows (e.g. from the power supply through the pull-up switching device for the clock-pulse line) in the driver device during each clock pulse period (first a “high logic”, and subsequently a “low logic” clock signal (or vice versa)), and then—e.g. from the clock signal line through the pull-down switching device to ground—a discharge current (or vice versa) flows.

This charging current places a relatively heavy load on the power supply of the driver device (for instance by flowing through the pull-up switching device). As a consequence, the charging or discharging currents flowing through the pull-up and pull-down switching devices cause an (unwanted) heating up of the driver device.

To prevent the clock pulse signal emitted by the pulse generator device (and/or driver device) via the clock signal line to the semi-conductor components (and/or the clock signal pins) from being reflected, the input impedance of the semi-conductor components (and/or the corresponding clock signal pins) are adapted—as closely as possible—to the impedance of the clock signal line (e.g. by means of appropriate adjustments to the line and/or terminal resistors).

The signal reflections caused at the semi-conductor component inputs by a (never completely avoidable) maladjustment lead to a distortion of the clock signal, which may cause errors in the chronological co-ordination and/or synchronization of the data relaying and/or processing and/or transfer.

The above effect is amplified by (similarly never an/or never completely avoidable) signal reflections at bifurcations in the clock signal line, which may lead to additional distortion of the clock pulse signal.

### SUMMARY OF THE INVENTION

The invention provides a synchronizer signal generator device, as well as a process for generating a synchronizer signal, in particular a clock signal, e.g. for semi-conductor components.

According to one embodiment of the invention, a synchronizer signal generator device connected to an electronic system is provided, and emits a synchronizer signal of a particular frequency that is transferred to at least one device, in particular a semi-conductor component of the electronic system, wherein at least one device is provided such that the impedance has been selected to create a resonating circuit—for the synchronizer signal generator device—of which the resonance frequency is essentially identical to the frequency of the synchronizer signal.

In this way, even when the signal emitted by the synchronizer signal generator device (and/or a driver device provided there) has a relatively small amplitude, the synchronizer signal received by the semi-conductor component is sufficiently powerful (in particular sufficiently efficient) in the built-up state (i.e. even at a relatively small power consumption level by the driver device and/or relatively small load on its current or voltage).

As a result of the lower load on the current and/or voltage supply of the device, the latter is less strongly heated than conventional devices.

### BRIEF DESCRIPTION OF THE DRAWINGS

The invention is described below with reference to exemplary embodiments and the accompanying drawings. In the drawings:

FIG. 1 shows a synchronizer signal generator device used in an embodiment example of the present invention, along with semi-conductor components synchronized by the synchronizer signal generator device.

FIG. 2 shows a switching and/or substitute switching circuit diagrams to illustrate the function and/or operation of the synchronizer signal generator device shown in FIG. 1, and of a synchronizer signal transferred via a synchronizer signal line to a semi-conductor component that needs to be synchronized.

FIG. 3 shows the chronological progression of a signal emitted by the signal source device of the synchronizer signal generator device.

FIG. 4 shows the chronological progression of the synchronizer signal used to synchronize the semi-conductor components.

FIG. 5 shows the output of the synchronizer signal in relation to the frequency.

### DETAILED DESCRIPTION OF THE INVENTION

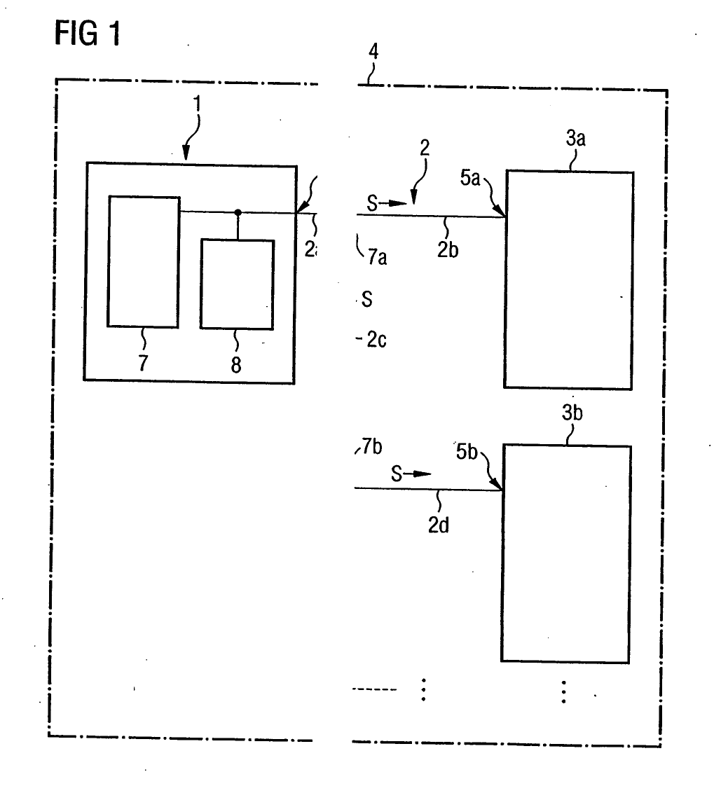

FIG. 1 is a schematic representation of the main construction of the synchronizer signal generator device 1 used in an embodiment example of the present invention, as well as several semi-conductor components 3a, 3b synchronized by the synchronizer signal generator device 1.

The semi-conductor components 3a, 3b may for instance be suitable integrated (analog and/or digital) computer circuits, and/or semi-conductor memory components such as functional memory components (PLAs, PALs, etc.) and/or table memory components (e.g. ROMs or RAMS), in particular SRAMs or DRAMs (here e.g. DRAMs (Dynamic Random Access Memories and/or dynamic Read/Write Memories) with double data rate (DDR DRAMs=Double Data Rate—DRAMs), preferably high-speed DDR DRAMs).

The semi-conductor components 3a, 3b and the synchronizer signal generator device 1 may be connected to a component module 4, e.g. to the corresponding card of a memory card module, which can for instance be built into a stationary or mobile computer system, or e.g. into a stationary or mobile telephone, etc.

The terminals of the semi-conductor components 3a, 3b and the synchronizer signal generator device 1 can be connected to the component module by means of suitable conventional soldered connections.

FIG. 1 shows a corresponding output terminal 6a of the synchronizer signal generator device 1 connected to one or more corresponding synchronizer signal and/or clock pulse signal lines 2, on or in the above card, with corresponding terminals 5a, 5b connected to the semi-conductor components 3a, 3b (in particular to special synchronizer and/or clock pulse signal pins (and/or corresponding synchronizer signal inputs) provided on the semi-conductor components 3a, 3b).

As FIG. 1 further shows, and as is illustrated in more detail below, a synchronizer and/or clock pulse signal S emitted at output 6a of the synchronizer signal generator device 1 is led to a synchronizer signal and/or clock pulse signal single line 2a that is connected to the output terminal 6a, which is split at one or more bifurcations 7a, 7b into one or more further synchronizer signal and/or clock pulse signal single lines 2b, 2c, 2d, which relay the synchronizer and/or clock pulse signal S to the semi-conductor components 3a, 3b, and/or their connections 5a, 5b (or also to one or more further components not illustrated here).

As is more closely illustrated below, the synchronizer signal generator device 1 (and/or the corresponding synchronizer signal generator component 1, connected to the module and/or the card 4 as of described above) has a driver device 7 (and/or a corresponding driver circuit 7), as well as a resonator and/or compensator device 8 (and/or a corresponding resonator and/or compensator circuit (and/or a resonance adjustment circuit 8)).

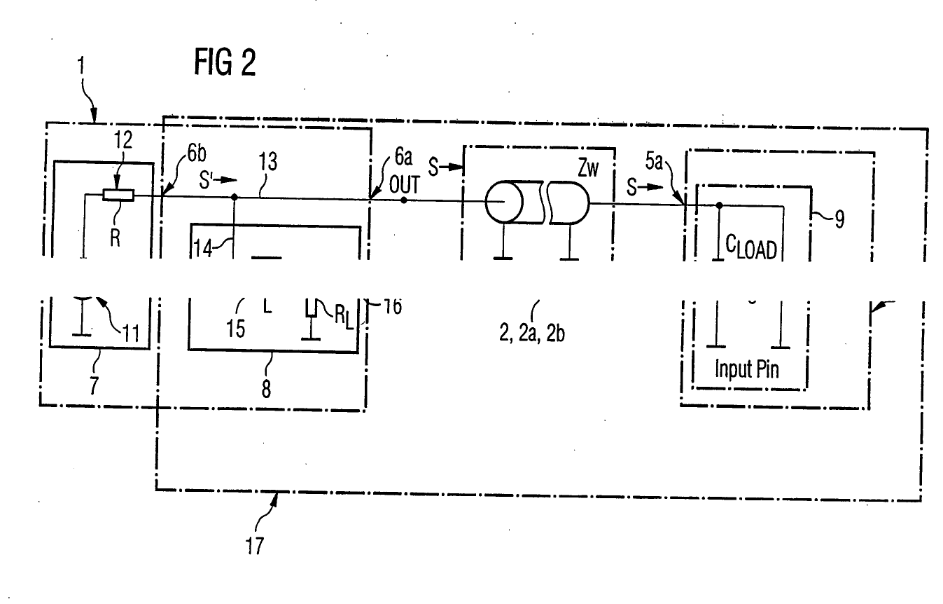

FIG. 2 is a schematic representation of switching and/or substitute circuit diagrams to illustrate the functioning or operation of the synchronizer signal generator device 1 shown in FIG. 1, and of the synchronizer signal S transferred via one or more synchronizer signal lines 2, 2a to a semi-conductor component 3a that needs to be synchronized.

The semi-conductor component 3a (and/or more specifically its synchronizer signal input 9 (and/or input pin 9)) has a particular input capacitance C_{LOAD} (here illustrated by the condenser 10a), as well as a particular leak resistance R_{c} (here illustrated by the resistor 10b) due to small currents flowing down the housing of the semi-conductor component 3a.

The above input capacitance C_{LOAD}, and the leak resistance R_{c}—approximately—mirror the electrical characteristics of the semi-conductor component synchronizer signal input 9 (and/or input pins 9). The input capacitance C_{LOAD} (i.e. the capacitance of the condenser 10a that illustrates this) may for instance lie between 1 pF and 10 pF, e.g. 3 pF, and the leak resistance R_{c} (i.e. the resistance of the resistor 10b that illustrates this) for instance between 1 MΩ and 50 MΩ, e.g. 10 MΩ.

The synchronizer signal line (and/or lines) 2, 2a, 2b that connects the synchronizer signal generator device 1 and the semi-conductor component 3a (and/or more accurately, their synchronizer signal input 9) represent in total the wave resistance Z_{w} (e.g. a wave resistance Z_{w} of between 10 Ω and 100 Ω, e.g. 50 Ω) that mirrors the electrical characteristics of the synchronizer signal line (and/or lines) 2, 2a, 2b (in particular at the frequency f of the synchronizer signal S) (see below).

As further shown in FIG. 2, the driver device 7 of the synchronizer signal generator device 1 has a signal-generating device 11 (and/or voltage source 11) that delivers a—periodic—signal S′ (and/or S″ or S″′).

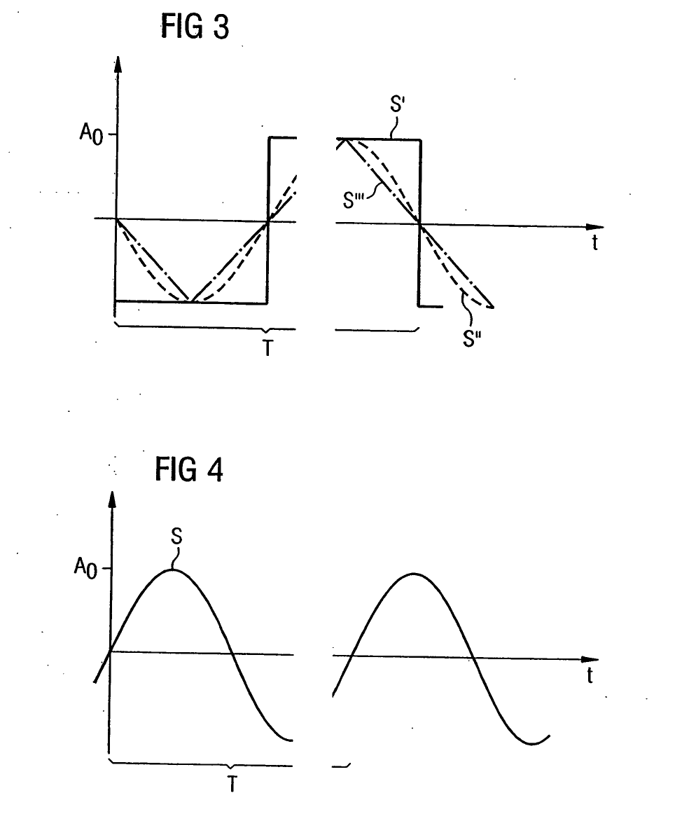

The periodic signal S′, S″, S″′ generated by the signal generator device 11 (and/or the periodically varying voltage U generated by the voltage source 11)—may, as shown in FIG. 3—for instance be a corresponding rectangular signal S′ and/or a rectangular voltage U (cf. the signal shape shown in FIG. 3 by the solid line), or if required, alternatively also another periodic signal S″, S″′, e.g. a corresponding sinus signal S″ (shown in FIG. 3 by a broken line), or e.g. a corresponding saw-toothed signal S″′ (shown in FIG. 3 by a dotted line) etc.

For generating a rectangular signal S′ the signal source device 11 of the driver device 7 may—as with conventional driver devices—for instance have a pull-up and a pull-down switching device.

The pull-up switching device may, for example, be connected to the supply voltage, and the pull-down switching device, for example, connected to ground. The pull-up and pull-down switching devices are connected in series and may in each case have one or more transistors (preferably connected in parallel), whereby the transistor(s) provided in the pull-up switching device may be inverted in relation to the transistor(s) of the pull-down switching device.

As an example, the pull-up switching device may have one or several p-channel MOSFETS (in parallel), and the pull-down switching device one or several n-channel MOSFETs connected in parallel.

The rectangular signal S′ generated by signal source 11 (and/or its pull-up and pull-down switching device) is—as shown in FIG. 3—alternately “high logic” and “low logic”.

For emitting a “high logic” clock pulse signal, the pull-up switching device may for instance be switched on, i.e. brought into a conductive state, and the pull-down switching device switched off, i.e. brought into a non-conductive state—at which a “high logic” signal will be emitted at output 6b of the driver device (and/or a line 13 connected to it) lying between the pull-up and the pull-down switching devices.

Conversely for emitting a “low logic” signal, the pull-up switching device may be switched off, i.e. brought into a non-conductive state, and the pull-down switching device switched on, i.e. brought into a conductive state—whereby the clock pulse signal emitted at output 6b of the driver devices (and/or line 13) will then be “low logic”.

The pull-up and pull-down switching device is controlled in such a way by a suitable control device (e.g. with a quartz oscillator) that a “high logic” and a “low logic” signal (i.e. the above rectangular signal S′) is alternately emitted at the driver device output 6b (and/or line 13) in a strictly regular chronological sequence.

If the signal source device 11 is to emit a sinus signal S″ (or e.g. a saw-toothed signal S″′, etc.) instead of a rectangular signal S′, a corresponding conventional sinus signal source device (or e.g. a saw-toothed signal source device, etc.) may be used.

As FIG. 3 further shows, the signal S′, S″, S″′emitted by signal source device 11, has a particular, constant, periodic duration T (and/or a particular, constant frequency f, whereby T=1/f), e.g. a frequency f of between 10 MHz and 1 GHz, e.g. 100 MHz).

The signal source device 11 (and/or the driver device 7) has a particular output resistance R (here represented by the resistor 12), e.g. an output resistance R of between 5 Ω and 50 Ω, e.g. 20 Ω.

As seen in FIG. 2, the output 6b of the driver device 7 is connected (e.g. via one of the above lines 13 and one of its branch lines 14) to the resonator device 8, in particular to a resonator and/or commutation coil 15 (e.g. a coil constructed as an SMD component) provided there.

The coil 15 has a particular internal resistance R_{L} (here represented by the resistor 16), e.g. an internal resistance R_{L} of between 0,02 Ω and 1 Ωe.g. 0,1 Ω.

Due to the inductance L of the coil 15, the resonator device 8 acts as a low-pass filter for the (rectangular) signal S′ emitted by the signal source device 11.

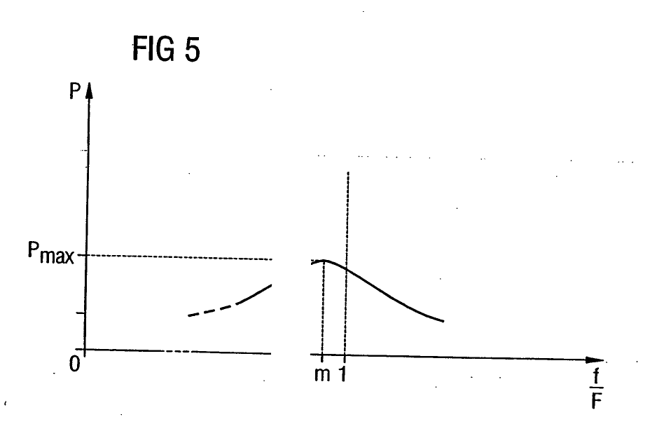

The rectangular signal S′ emitted by the signal source device 11 is smoothed out to such an extent by the low—pass filter formed by the resonator device 8 that—as illustrated in FIG. 4—the synchronizer signal S emitted at output connection 6a of the synchronizer signal generator device 1 (connected to the driver device output 6b via line 13) assumes an essentially sinusoid character (with a correspondingly identical constant duration period T and/or an identical, constant frequency f to that of the signal S′, S″, S″′ emitted by the signal source device 11, although with a phase shift in relation to it (see below)).

To achieve this, the inductivity of the coil 15 may be so chosen that the cut-off frequency f_{g} of the low-pass filter—formed by the resonator-device 8—is higher than the frequency f of the rectangular signal S emitted by the signal source device 11 (although possibly smaller than the spectral portions of a higher order contained in the rectangular-signal S′ (i.e. the spectral portions with a frequency higher than the (grand) frequency f of the rectangular signal S′).

The resonator device has been constructed in such a way—in particular by the appropriate choice of the inductivity L of coil 15—that as a result a “resonance circuit” 17 (consisting of a resonator device 8, a synchronizer signal line 2, 2a, and a semi-conductor component 3a (and/or semi-conductor components 3a, 3b connected to it), is created for the driver device 7, by additionally taking into consideration the electrical characteristics, for instance of the synchronizer signal line 2, 2a (in particular the surge impedance Z_{w} of the synchronizer signal line 2, 2a (inter alia influenced by the length of the line), and/or of the semi-conductor component synchronizer signal input 9 (in particular its input capacitance C_{LOAD}), etc.

The resonance frequency F of the oscillatory circuit created by the resonating circuit 17, is chosen in such a way—in particular by the appropriate choice of the inductivity L of the coil 15—that it essentially matches (and/or possibly as closely as possible) the frequency f of the signal S′, S″, S″′ emitted by the signal source device 11 (and/or the frequency f of the synchronizer signal S emitted by the synchronizer signal generator device 1), or is minimally larger or smaller.

For instance, the resonance frequency F of the “resonance circuit” 17 (formed by the resonator device 8, the synchronizer signal line 2, 2a, and the semi-conductor component 3a connected to it) may be correspondingly chosen in such a way that the following applies: 0,6 f<F<1,3 f, in particular 0,8 f<F<1,2 f, particularly advantageous is 0,9 f<F<1,1 f.

For example, the inductivity L of the coil 15 amounts to 500 nH (in particular at the above—exemplary—values for the line wave resistance Z_{w}, semi-conductor component input capacitance C_{LOAD}, etc.) e.g. between 200 nH and 1000 nH, in particular between 400 nH and 600 nH.

The adjustment of the resonating frequency F to the above value—adjusted to the frequency f of the signals S, S′, S″, S″′—(and/or the adjustment of the “resonating circuit” 17 to the signal frequency f) may also or additionally be done for the above coil 15, for instance by selecting an appropriately dimensioned capacitance—e.g. provided in the resonator device 8, in the semi-conductor component 3a, etc. (e.g. connected in parallel or in series for the coil 15), and/or by the choice of the appropriate length and/or placing of the lines, etc.

Preferably the electrical characteristics of the module 4 (and/or of the synchronizer signal generator device 1 and/or the synchronizer signal lines 2, 2a, 2b and/or the semi-conductor components 3a, 3b) are already selected during the of design of component module 4 (shown in FIG. 1) and/or the synchronizer signal generator device 1 and/or the synchronizer signal lines 2, 2a, 2b and/or the semi-conductor components 3a, 3b—i.e. before manufacturing and commissioning—so that the resonance frequency F of the oscillatory circuit created by the resonance circuit 17 essentially resembles (and/or as closely as possible) the signal frequency f.

Alternatively (or additionally) a (fine) adjustment of the resonance frequency F may be done after manufacturing the component module 4 (and/or the synchronizer signal generator device 1 and/or the synchronizer signal lines 2, 2a, 2b and/or the semi-conductor components 3a, 3b).

This may also be achieved by providing—additionally or as an alternative to the above coil 15—one or several adjustable inductances (e.g. in the resonator device 8, and/or in the semi-conductor component 3a, 3b, etc., for instance in the shape of appropriate inductive components—corresponding to the of desired inductivity value—switched on or switched off, or able to be switched on or off), and/or as an addition or alternative to the above capacitor provided as an addition or alternative the above coil 15, for instance in the resonator device 8, or in the semi-conductor component 3a, etc., one or more adjustable capacitors (e.g. one or more or several capacitive diodes connected in parallel or in series for the coil 15, of which the capacitance can be accurately adjusted to the of desired (resonance) value during the later operation of the component module 4—e.g. by providing an appropriate control voltage).

Because—as of described above—the resonance frequency F of the oscillatory circuit created by resonance circuit 17 is essentially identical to the signal frequency f of the (synchronizer) signals S, S′, S″, S″′, the power P of the synchronizer signal S in the built-up stage is relatively large—as shown in FIG. 5—in particular when—and especially preferable—the resonance frequency F is adjusted in such a way that the resonance circuit 17—in relation to the signal frequency f (taking the circuit quality into consideration)—is operated at and/or as close to the so-called resonance maximum m (whereby the signal frequency f is somewhat smaller than the resonance frequency F, and whereby a maximum value Pₘₐₓ for the synchronizer signal power P is achieved).

Thereby the built-up synchronizer signal S received by the semi-conductor component 3a, 3b—even at relatively minor power consumption of the driver device 7 (and/or at relatively minor loading of its current and/or voltage supply)—is strong enough (in particular shows an adequate power level P). Due to the lower load on the current and/or voltage consumption of the driver device 7, the latter is heated up less strongly than conventional driver devices.

As can be seen from the embodiment example in FIG. 2, and the special synchronizer signal S used there, separate line terminators (commonly used in conventional semi-conductor components, e.g. connected between the signal input 9 and ground and/or supply voltage) may be dispensed with. This causes—in contrast to conventional driver devices—a further reduction in power consumption by and heating of the driver device 7.

The synchronizer signal S is used in the semi-conductor component 3a, 3b for the chronological co-ordination of the processing (and/or relaying and/or transfer) of data.

For example, the processing and/or relaying and/or transfer of data in the semi-conductor component 3a, 3b can take place at each (or e.g. each second) zero pass of the synchronizer signal S, and/or with an appropriate phase shift, etc.

To increase the accuracy of the chronological co-ordination of the processing/relaying/transfer of data, the frequency f of the synchronizer signal S may be increased by a certain factor, e.g. twice, three times or four times higher than the frequency of component clock pulse T generated by the pulse generator device in the semi-conductor component 3a, 3b controlled by the synchronizer signal S.

A suitable frequency divider can for example be used to generate the corresponding component clock pulse T from the—frequency-multiplied—synchronizer signal S.

Alternatively or additionally (in particular for a (further) increase in the (phase) accuracy) of a particular semi-conductor component 3a—one or several—corresponding to the synchronizer signal S—further synchronizer signals (e.g. a further synchronizer signal S inverted in relation to the synchronizer signal S, or shifted out of phase in some other way) may be applied in addition to the above synchronizer signal S—produced by the synchronizer signal generator device 1 (or a corresponding further synchronizer signal generator device, not shown here), via line 2, 2a through one or several further synchronizer signal lines, not shown here.

For (further) increasing (phase) accuracy—alternatively or additionally to the process of described above—the phase-position of the synchronizer signal S (and/or of the further synchronizer signal S) in the semi-conductor component 3a may be evened out over several periods (e.g. by means of a suitable PLL circuit provided on the semi-conductor component 3a and controlled by the synchronizer signal S).

Where a PLL circuit (PLL=phase locked loop) is used, the frequency of a separately provided oscillator, in particular a voltage-controlled oscillator, is adjusted in such a way—corresponding to conventional PLL circuits—that it corresponds with a reference frequency, here frequency f of the synchronizer signal S.

For example, the signal generated by the voltage-regulated oscillator, and the synchronizer signal S in the PLL-circuit may be led to a phase comparator (e.g. to an analog multiplier).

If the two signals differ, a signal appears at the output of the phase comparator, which may then be relayed e.g. to a low-pass filter and an amplifier, and which then controls the oscillator in such a way that the frequency of the oscillator and that of the synchronizer signal S finally coincide.

Instead of a PLL circuit, a DLL circuit may for example also be used as an alternative.

A DLL circuit is manufactured without a separate oscillator and generates an output signal delayed in relation to synchronizer signal S.

By means of a DLL circuit it is in particular possible to correct a constant phase error.

What is claimed is:

1. A synchronizer signal generator device, which is connected to an electronic system, and which emits a synchronizer signal of a particular frequency, which is transferred to at least one device of the electronic system, wherein the at least one device, of which an impedance is chosen such that a resonance-oscillatory circuit is created, for the synchronizer signal generator device, of which the resonance frequency essentially coincides with the frequency of the synchronizer signal.

2. The synchronizer signal generator device according to claim 1, wherein the synchronizer signal received by the device is essentially sinusoid.

3. The synchronizer signal generator device according to claim 1, further comprising a driver device for generating the synchronizer signal.

4. The synchronizer signal generator device according to claim 3, wherein the driver device generates an essentially rectangular signal.

5. The synchronizer signal generator device according to claim 4, wherein the rectangular signal generated by the driver device is filtered such that the signal emitted by the synchronizer signal generator device is essentially sinusoid.

6. The synchronizer signal generator device according to claim 1, further comprising at least one impedance device, which has an inductive component.

7. The synchronizer signal generator device according to claim 6, wherein the at least one impedance device has a capacitive component.

8. The synchronizer signal generator device according to claim 7, wherein an inductivity and/or capacitance adjustment of the inductive and/or capacitive component is set during manufacture.

9. A synchronizer signal generator device according to claim 8, wherein the inductivity and/or the capacitance of the inductive and/or capacitive component is variably adjustable after manufacture.

10. The synchronizer signal generator device according to claim 9, wherein the capacitive component is a capacitive diode.

11. The synchronizer signal generator device according to claim 1, wherein the device to which the synchronizer signal is transferred, is a semi-conductor component.

12. The synchronizer signal generator device according to claim 1, wherein the synchronizer signal of the device is used for chronological co-ordination of relaying and/or processing and/or transfer of data.

13. The synchronizer signal generator device according to claim 1, wherein the device generates a further signal under control of the synchronizer signal, which is used for chronological co-ordination of relaying and/or processing and/or transfer of data.

14. The synchronizer signal generator device according to claim 13, wherein the further signal has a lower frequency than the synchronizer signal.

15. The synchronizer signal generator device according to claim 14, wherein a PLL or DLL circuit is used to generate the further signal.

16. A process for generating a synchronizer, comprising:
emitting a synchronizer signal by a synchronizer signal generator device to at least one device of an electronic system; and
providing the at least one device in the synchronizer signal generator device and/or the electronic system, of which an impedance has been selected such that, for the synchronizer signal generator device, a resonance-oscillatory circuit is created, of which the resonance frequency essentially coincides with a frequency of the synchronizer signal.
